(19) United States
(12) Patent Application Publication
(10) Pub. No.: US 2021/0034825 A1
(43) Pub. Date: Feb. 4, 2021

(54) CONNECTOR

(71) Applicant: Japan Aviation Electronics Industry, Limited, Tokyo (JP)

(72) Inventor: Tomohiro NAKAMURA, Tokyo (JP)

(73) Assignee: Japan Aviation Electronics Industry, Limited, Tokyo (JP)

(21) Appl. No.: 16/891,196

(22) Filed: Jun. 3, 2020

(30) Foreign Application Priority Data
Jul. 31, 2019 (JP) 2019-141162

(51) Int. Cl. G06K 7/00; H05K 5/02

(52) U.S. Cl. CPC G06K 7/003; H05K 5/0226; H05K 5/0239; G06K 7/0073

(57) ABSTRACT

A connector comprises a base and a cover. The base is formed with a card-accommodation portion in which a card is accommodatable. The cover is attached to the base via a hinge mechanism to be locatable at a close position. The cover located at the close position covers, at least in part, the card-accommodation portion from above. The cover has two card-holding portions. The base has two regulating portions which correspond to the card-holding portions, respectively. Each of the card-holding portions has an outside portion. When the cover is located at the close position, each of the regulating portions is located inward of the outside portion of the corresponding card-holding portion in the pitch direction (Y-direction) and is located at a position different from that of the outside portion of the corresponding card-holding portions in the front-rear direction (X-direction).

### CROSS REFERENCE TO RELATED APPLICATIONS

This application is based on and claims priority under 35 U.S.C. § 119 to Japanese Patent Application No. JP2019-141162 filed Jul. 31, 2019, the content of which is incorporated herein in its entirety by reference.

### BACKGROUND OF THE INVENTION

This invention relates to a connector configured to accommodate a card and to be electrically connected with the card.

For example, this type of connector is disclosed in JP2006-210126A (Patent Document 1), the content of which is incorporated herein by reference.

Referring to FIG. 11, Patent Document 1 discloses a connector 90 configured to accommodate a card (not shown) and to be connected with the card. For example, the card is a subscriber identity module (SIM) card formed with a plurality of electrodes. The connector 90 comprises a body portion (base) 92, a tray (cover) 94 and a plurality of contact elements (contacts) 96. The contacts 96 are held by the base 92 and are arranged in a pitch direction. The cover 94 has two card-holding portions 942. The cover 94 further has two tabs 948. The base 92 is formed with two holes 928 which correspond to the tabs 948, respectively. Each of the tabs 948 is inserted into the corresponding hole 928, so that the cover 94 is attached to the base 92 to be rotatable and slidable relative to the base 92. Thus, the cover 94 is attached to the base 92 via a hinge mechanism including the tabs 948 and the holes 928. When the cover 94 with a card held by the card-holding portions 942 is turned down toward the base 92 and is made slide, the contacts 96 are brought into contact with the electrodes of the card, respectively.

When a cover is attached to a base via a hinge mechanism such as that of Patent document 1, the hinge mechanism needs to be provided with play that allows the cover to be moved. However, such play may cause an irregular movement of the cover relative to the base, so that the card held by the cover may take an irregular position in a pitch direction. For example, in a structure in which a large number of contacts are arranged in the pitch direction with narrow intervals, when the card is in an irregular position in the pitch direction, each electrode of the card might be misaligned with the corresponding contact in the pitch direction and might not be brought into contact with the corresponding contact as designed. Thus, reliability of electrical connection between the electrode and the contact might be degraded.

### SUMMARY OF THE INVENTION

It is therefore an object of the present invention to provide a connector configured to reduce a shift of a card in a pitch direction.

An aspect of the present invention provides a connector connectable to a card. The connector comprises a base, a plurality of contacts and a cover. The base holds the contacts. The contacts are arranged in a pitch direction. The base is formed with a card-accommodation portion in which the card is accommodatable. The cover has a cover body portion and two card-holding portions. Each of the card-holding portions is connected to the cover body portion. The two card-holding portions are apart from each other in the pitch direction and are arranged to sandwich and hold the card therebetween in the pitch direction. The cover is attached to the base via a hinge mechanism and is movable relative to the base between an open position and a close position. When the cover is located at the open position, the card-accommodation portion is exposed upward in an upper-lower direction perpendicular to the pitch direction. When the cover is located at the close position, the cover body portion covers, at least in part, the card-accommodation portion from above, and each of the card-holding portions is located, at least in part, in the card-accommodation portion. The base has two regulating portions which correspond to the card-holding portions, respectively. The two regulating portions are apart from each other in the pitch direction. Each of the regulating portions faces inward in the pitch direction. Each of the card-holding portions has an outside portion which faces outward in the pitch direction. When the cover is located at the close position, each of the regulating portions is located inward of the outside portion of a corresponding one of the card-holding portions in the pitch direction and is located at a position different from that of the outside portion of the corresponding one of the card-holding portions in a front-rear direction perpendicular to both the pitch direction and the upper-lower direction. When the cover is located at the close position under a state where the card is held by the card-holding portions, the two regulating portions sandwich the card therebetween in the pitch direction and regulate a movement of the card in the pitch direction.

According to an aspect of the present invention, when the cover is located at the close position, each of the regulating portions is located at a position different from that of the outside portion of the corresponding card-holding portions in the front-rear direction and is located inward of the outside portion of the corresponding card-holding portions in the pitch direction. This arrangement enables the two regulating portions to directly sandwich the card in the pitch direction when the cover with the card held by the card-holding portions is located at the close position. By making the distance dimension in the pitch direction between the two regulating portions almost equal to the size of a card in the pitch direction, the movement of the card in the pitch direction can be reduced even when the cover is irregularly moved relative to the base. Thus, the present invention provides a connector configured to reduce a shift of a card in the pitch direction.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a perspective view showing a connector according to an embodiment of the present invention, wherein a cover is located at an open position, and a part of the connector enclosed by dashed line is enlarged and illustrated.

FIG. 2 is a top view showing the connector of FIG. 1.

FIG. 3 is a perspective view showing the connector of FIG. 1 along a direction opposite to that of FIG. 1, wherein the cover is located at a close position, and two parts of the connector each enclosed by dashed line are enlarged and illustrated.

FIG. 4 is a top view showing the connector of FIG. 3.

FIG. 5 is a top view showing parts of the connector enclosed by dashed line A, B, C and D of FIG. 4.

FIG. 6 is a perspective view showing the connector of FIG. 1, wherein the cover is located at the open position and holds a card.

FIG. 7 is a top view showing the connector of FIG. 6, wherein a hidden outline of a cover body portion of the cover is illustrated with dashed line.

FIG. 8 is a perspective view showing the connector of FIG. 6 along a direction opposite to that of FIG. 6, wherein the cover is located at the close position.

FIG. 9 is a top view showing the connector of FIG. 8, wherein positions of hidden contact portions of contacts are illustrated with dashed line.

FIG. 10 is a top view showing a part of the connector enclosed by chain dotted lines E of FIG. 9.

FIG. 11 is a perspective view showing a connector of Patent Document 1.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

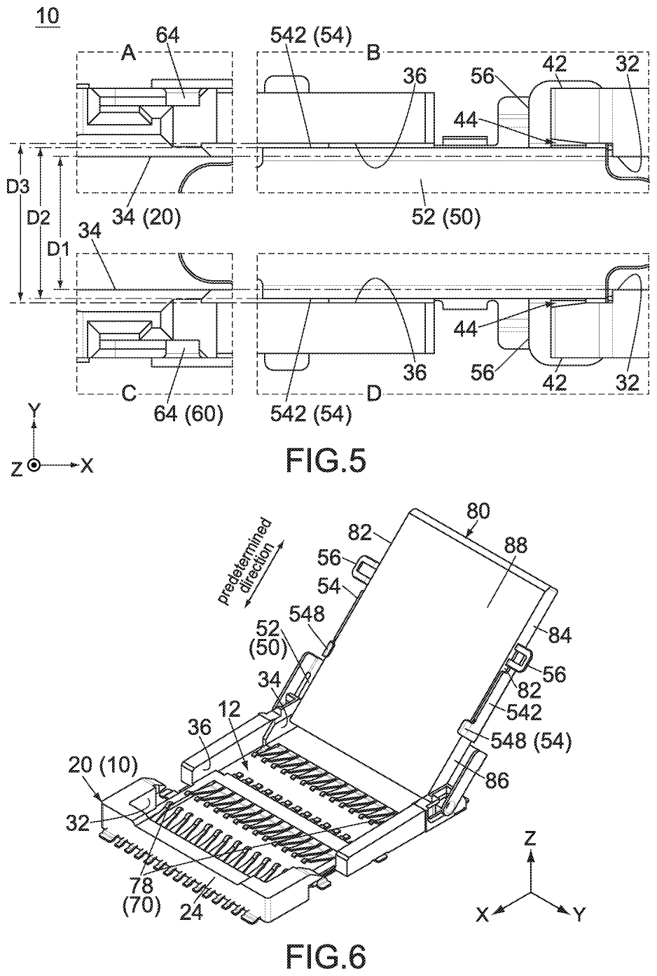

Referring to FIG. 6, a connector 10 of an embodiment of the present invention is a card connector which is electrically connectable with a card 80 formed with a plurality of electrodes (not shown). The card 80 of the present embodiment has a contact surface 88 that is formed with a plurality of the electrodes. The connector 10 of the present embodiment is a card connector which electrically connects the electrodes of the card 80 with conductive patterns of a circuit board (not shown), respectively. However, the present invention is not limited to the connector 10 but is applicable to various card connectors.

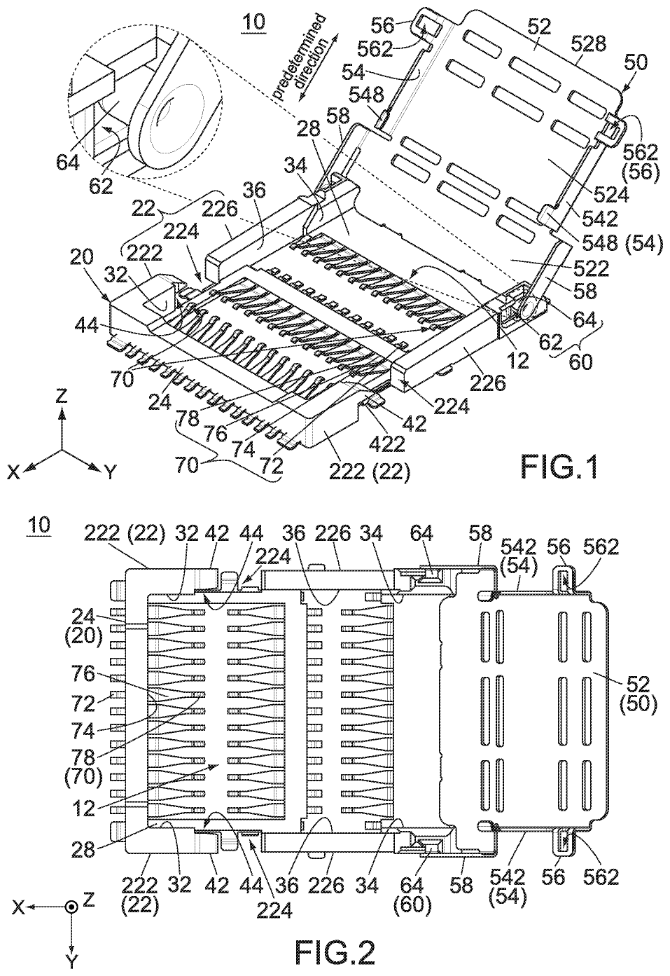

Referring to FIGS. 1 and 2, the connector 10 comprises a base 20 made of insulator, a plurality of contacts 70 each made of conductor and a cover 50 made of metal.

The base 20 of the present embodiment has two sidewalls 22, a front wall 24 and a bottom portion 28. The sidewalls 22 are located at opposite sides of the base 20 in a pitch direction (Y-direction), respectively, and extend in parallel to each other along a front-rear direction (X-direction) perpendicular to the Y-direction. The front wall 24 is located at a front end (positive X-side end) of the base 20. The bottom portion 28 is located at a lower end (negative Z-side end) of the base 20 in an upper-lower direction (Z-direction) perpendicular to both the X-direction and the Y-direction.

According to the present embodiment, each of the sidewalls 22 is formed with a cutout portion 224, so that the sidewall 22 is separated into two parts, namely a front portion 222 and a rear portion 226. Each of the front portions 222 is a front part (positive X-side part) of the sidewall 22 and extends along the X-direction. Each of the rear portions 226 is a rear part (negative X-side part) of the sidewall 22 and extends along the X-direction. The front wall 24 extends along the Y-direction and couples front ends of the front portions 222 to each other. The bottom portion 28 extends along the XY-plane (horizontal plane). The bottom portion 28 is formed with two holes which cut most of the bottom portion 28 and pass therethrough in the Z-direction.

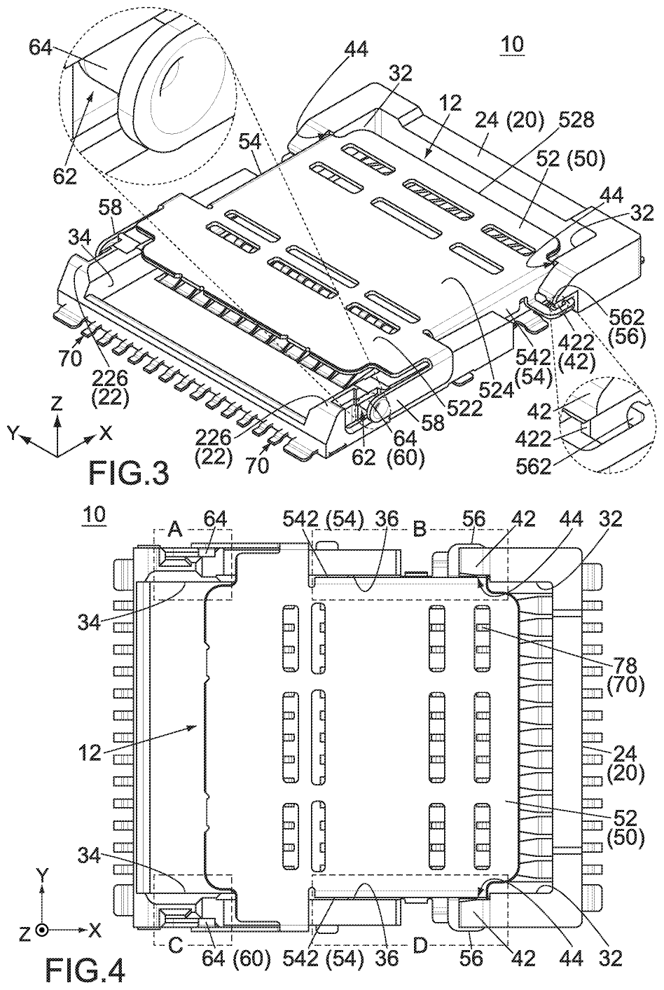

Referring to FIGS. 3 and 8, the base 20 is formed with a card-accommodation portion 12 in which the card 80 is accommodatable. Referring to FIGS. 1 and 2, the card-accommodation portion 12 of the present embodiment is a space enclosed by the sidewalls 22, the front wall 24 and the bottom portion 28 of the base 20.

The base 20 of the present embodiment has the structure described above. However, the present invention is not limited thereto but the structure of the base 20 can be modified variously. For example, the cutout portions 224 may be provided as necessary. In other words, the front portion 222 and the rear portion 226 of each of the sidewalls 22 may extend continuously with no break along the X-direction.

The contacts 70 of the present embodiment have shapes same as one another. Each of the contacts 70 of the present embodiment is a single metal plate with bends and has a fixed portion 72, a held portion 74, a spring portion 76 and a contact portion 78. When the connector 10 is used, each of the fixed portions 72 is fixed on and connected to a conductive pad (not shown) on the circuit board (not shown) via soldering, etc. Each of the held portions 74 is insert-molded in the bottom portion 28 of the base 20 and is held by the bottom portion 28. Thus, the base 20 holds the contacts 70. Each of the spring portions 76 extends from the held portion 74 in the X-direction and is resiliently deformable. Each of the contact portions 78 is supported by the spring portion 76 and is movable in the Z-direction. Each of the contact portions 78 is located at an upper end (positive Z-side end) of the contact 70 when the spring portion 76 is not resiliently deformed.

Each of the contacts 70 of the present embodiment has the structure described above. The contacts 70 are grouped into three rows in the X-direction. The contacts 70 of each row are arranged in the Y-direction. However, the structure of each of the contacts 70 and the arrangement of the contacts 70 are not limited to those of the present embodiment, provided that the connector 10 comprises two or more of the contacts 70 arranged in the Y-direction.

Referring to FIGS. 1 and 3, the cover 50 of the present embodiment is formed by bending a single metal plate and has a cover body 52, two card-holding portions 54 and two axis-support portions 58.

The cover body 52 of the present embodiment is a metal plate which has a flat plate-like shape and is formed with a plurality of holes. The cover body 52 extends along an intersection plane in parallel to the Y-direction. The intersection plane is oblique to the Z-direction when the cover 50 is in a position shown in FIG. 1 and is perpendicular to the Z-direction when the cover 50 is in another position shown in FIG. 3. The cover body 52 has a base portion 522 of a rectangular shape and an extension portion 524 of another rectangular shape. The base portion 522 protrudes beyond the extension portion 524 on both sides in the Y-direction. The extension portion 524 shown in FIG. 1 is located above (positive Z-side of) the base portion 522 and has an end 528 which is located at an upper end of the cover body 52. The extension portion 524 shown in FIG. 3 is located forward of (positive X-side of) the base portion 522, so that the end 528 is located at a front end of the cover body 52.

Each of the card-holding portions 54 and the axis-support portions 58 of the present embodiment is connected to the cover body 52. Each of the card-holding portions 54 is a flat plate-like metal piece which is bent to be perpendicular to the Y-direction. Each of the card-holding portions 54 is connected to an edge of the extension portion 524 of the cover body 52 in the Y-direction and extends along an intersection direction perpendicular to the Y-direction. The intersection direction is oblique to the Z-direction when the cover 50 is in the position shown in FIG. 1 and is perpendicular to the Z-direction when the cover 50 is in the position shown in FIG. 3. Each of the axis-support portions 58 is a flat plate-like metal piece which is bent to be perpendicular to the Y-direction. Each of the axis-support portions 58 is partially connected to an edge of the base portion 522 in the Y-direction and extends along the intersection direction.

Referring to FIGS. 1 and 2, the cover 50 of the present embodiment has two locked portions 56 which correspond to the card-holding portions 54, respectively. Each of the locked portions 56 is provided on one of opposite ends of the corresponding card-holding portion 54 in the intersection direction, which is nearer to the end 528 than the other of the opposite ends is. Each of the locked portions 56 extends outward from the corresponding card-holding portion 54 in the Y-direction. Each of the locked portions 56 is formed with an engagement hole 562 which passes through the locked portion 56.

The cover 50 of the present embodiment has the structure described above. However, the present invention is not limited thereto but the structure of the cover 50 can be modified variously. For example, the locked portions 56 may be provided as necessary.

Referring to FIG. 1, each of the card-holding portions 54 of the present embodiment has a holding projection 548. Each of the holding projections 548 is provided on one of the opposite ends of the card-holding portion 54 in the intersection direction, which is farther from the end 528 than the other of the opposite ends is. Each of the holding projections 548 projects inward from the card-holding portion 54 in the Y-direction. Referring to FIG. 6, the two card-holding portions 54 are apart from each other in the Y-direction. The two card-holding portions 54 which are formed as described above are arranged to sandwich and hold the card 80 therebetween in the Y-direction. Each of the card-holding portions 54 of the present embodiment has the structure described above. However, the present invention is not limited thereto but the structure of each of the card-holding portions 54 can be modified variously. For example, the holding projections 548 may be provided as necessary.

Referring to FIGS. 1 and 3, each of the axis-support portions 58 has an axis portion 64. Each of the axis portions 64 is located on one of opposite ends of the axis-support portion 58 in the intersection direction, which is farther from the end 528 than the other of the opposite ends is. Each of the axis portions 64 projects inward from the axis-support portion 58 in the Y-direction. The base 20 has two bearing portions 62 which correspond to the axis portions 64, respectively. The bearing portions 62 are recesses which are formed on the rear portions 226 of the two sidewalls 22, respectively. Each of the bearing portions 62 is in the vicinity of a rear end (negative X-side end) of the rear portion 226. Each of the bearing portions 62 is recessed inward in the Y-direction and opens outward in the Y-direction. Each of the bearing portions 62 extends in a predetermined range along the X-direction.

Each of the axis portions 64 is inserted into the corresponding bearing portion 62, so that the cover 50 is attached to the base 20 to be movable. More specifically, the cover 50 is rotatable about the axis portions 64 relative to the base 20. In addition, the cover 50 is slidable along the X-direction relative to the base 20 in accordance with a movement of the axis portions 64 along the bearing portions 62 within the predetermined range. Thus, the connector 10 comprises a hinge mechanism 60 which allows the cover 50 to be moved relative to the base 20. The hinge mechanism 60 is provided with play which allows the movement of the cover 50. The hinge mechanism 60 of the present embodiment is formed of the two axis portions 64 of the cover 50 and the two bearing portions 62 of the base 20. However, the present invention is not limited thereto but the structure of the hinge mechanism 60 can be modified variously.

The cover 50 is attached to the base 20 via the hinge mechanism 60 and is movable relative to the base 20 between an open position shown in FIG. 1 and a close position shown in FIG. 3. When the cover 50 is located at the position shown in FIG. 1, or at the open position, the card-accommodation portion 12 is exposed upward in the Z-direction. When the cover 50, which is located at the open position, is turned down toward the base 20, the cover 50 is located at an intermediate position (not shown). Meanwhile, the locked portions 56 of the cover 50 pass through the cutout portions 224 of the sidewalls 22 of the base 20, respectively, to be located at lower ends of the cutout portions 224, respectively. When the cover 50 is located at the intermediate position, the cover body 52 is located over the card-accommodation portion 12 and extends in parallel to the XY-plane. When the cover 50, which is located at the intermediate position, is made slide forward, the cover 50 is moved to the position shown in FIG. 3, or to the close position.

According to the present embodiment, the cover 50 is moved between the open position and the close position via the intermediate position (not shown). However, the present invention is not limited thereto. For example, when the cover 50 is turned down from the open position toward the base 20, the cover 50 may be moved directly to the close position without passing the intermediate position.

Referring to FIG. 3, in the present embodiment, when the cover 50 is located at the close position, the cover body 52 partially covers the card-accommodation portion 12 from above, and the most part of each of the card-holding portions 54 is located in the card-accommodation portion 12. However, the present invention is not limited thereto. For example, when the cover 50 is located at the close position, the cover body 52 may entirely covers the card-accommodation portion 12 from above, and each of the card-holding portions 54 may be entirely located in the card-accommodation portion 12. Thus, when the cover 50 is located at the close position, the cover body 52 may cover, at least in part, the card-accommodation portion 12 from above, and each of the card-holding portions 54 is located, at least in part, in the card-accommodation portion 12.

Referring to FIGS. 1 to 4, the base 20 of the present embodiment has two receiving portions 44 which correspond to the card-holding portions 54 of the cover 50, respectively, and has two lock portions 42 which correspond to the receiving portions 44, respectively. Referring to FIGS. 1 and 2, each of the lock portions 42 is located outward of the corresponding receiving portion 44 in the Y-direction. Each of the receiving portions 44 of the present embodiment is a space which is located forward of the cutout portion 224 of the sidewall 22 and communicates with the cutout portion 224 in the X-direction. Thus, each of the lock portions 42 and the receiving portions 44 is located at a rear end of the front portion 222 of the sidewall 22. However, the present invention is not limited thereto, but the positions of the lock portions 42 and the receiving portions 44 can be modified variously as necessary.

Referring to FIG. 3, each of the lock portions 42 of the present embodiment has a lower surface (negative Z-side surface) which is provided with an engagement projection 422. Each of the engagement projections 422 projects downward from the lower surface of the lock portion 42. When the cover 50, which is located at the intermediate position (not shown), is made slide forward relative to the base 20, the end of each of the card-holding portions 54 is inserted into the corresponding receiving portion 44. Meanwhile, a front end of each of the locked portions 56 is moved forward beyond the corresponding engagement projection 422 while being resiliently deformed downward. When the cover 50 is moved to the close position, each of the locked portions 56 returns to its shape before the resilient deformation, so that each of the engagement projections 422 is engaged with the corresponding engagement hole 562.

According to the present embodiment, when the cover 50 is located at the close position, each of the receiving portions 44 partially receives the corresponding card-holding portions 54, and each of the lock portions 42 locks the corresponding locked portion 56. Thus, the connector 10 of the present embodiment has a lock mechanism which locks the cover 50 at the close position. The lock mechanism of the present embodiment is formed of the two lock portions 42 and the two locked portions 56. The two lock portions 42 have the engagement projections 422, respectively. The two locked portions 56 have the engagement holes 562, respectively. However, the present invention is not limited thereto, but the structure of the lock mechanism can be modified variously. Moreover, the lock mechanism may be provided as necessary.

Referring to FIGS. 1 to 4, each of the card-holding portions 54 of the cover 50 has an outside portion (regulated portion) 542 which faces outward in the Y-direction. Each of the outside portions 542 of the present embodiment is an outer surface of the card-holding portion 54 in the Y-direction and is a plane in parallel to the XZ-plane (perpendicular plane). However, the present invention is not limited thereto. For example, each of the outside portions 542 may be a curved surface.

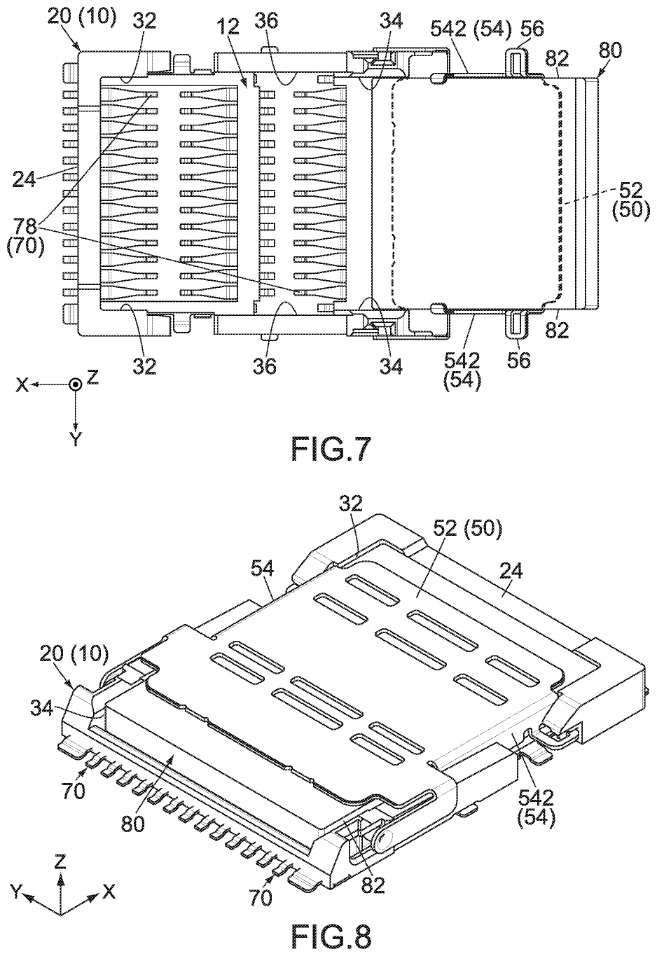

Referring to FIGS. 6 and 7, the card 80 has two side surfaces 82 which correspond to the card-holding portions 54, respectively. When the card 80 is held by the card-holding portions 54, the side surfaces 82 are located at opposite sides of the card 80 in the Y-direction, respectively, and extend along the intersection direction to be in parallel to the XZ-plane. When the card 80 is held as described above, the middle part of each of the side surfaces 82 in the intersection direction is covered by the outside portion 542 of the corresponding card-holding portion 54 which is located outward thereof in the Y-direction. Meanwhile, opposite ends of each of the side surfaces 82 in the intersection direction are exposed outward in the Y-direction. In detail, referring to FIGS. 6 and 9, each of the side surfaces 82 has a regulated surface 84 and an additional regulated surface 86. The regulated surface 84 and the additional regulated surface 86 are end portions of the side surface 82 in the intersection direction, respectively. Thus, the regulated surfaces 84 and the additional regulated surfaces 86 are located at four corners of the card 80, respectively, and are exposed outward in the Y-direction when the card 80 is held by the card-holding portions 54.

Referring to FIGS. 1 and 2, the base 20 has two regulating portions 32 which correspond to the card-holding portions 54 of the cover 50, respectively. Each of the regulating portions 32 of the present embodiment is an inner surface of the front portion 222 of the sidewall 22 in the Y-direction and is a plane in parallel to the XZ-plane (perpendicular plane). However, the present invention is not limited thereto, but the shape of each of the regulating portions 32 and the arrangement of the regulating portions 32 can be modified variously as necessary. For example, each of the regulating portions 32 may be a curved surface.

Referring to FIG. 2, each of the regulating portions 32 faces inward in the Y-direction. The two regulating portions 32 are apart from each other in the Y-direction. Referring to FIG. 5, in the present embodiment, the two regulating portions 32 are apart from each other by a distance D1 in the Y-direction, and the outside portions 542 of the two card-holding portions 54 are apart from each other by a distance D2 in the Y-direction. The distance D1 is shorter than the distance D2. Thus, when the cover 50 is located at the close position, or the position shown in FIG. 5, each of the regulating portions 32 is located inward of the outside portion 542 of the corresponding card-holding portion 54 in the Y-direction. When the cover 50 is located at the close position, each of the regulating portions 32 is located at a position different from that of the outside portion 542 of the corresponding card-holding portion 54 in the X-direction.

Referring to FIG. 9, according to the structure described above, when the cover 50 is located at the close position, or the position shown in FIG. 9, under a state where the card 80 is held by the card-holding portions 54, each of the regulating portions 32 is located outward of the regulated surface 84 of the card 80 in the Y-direction, so that the two regulating portions 32 sandwich the card 80 in the Y-direction and regulate a movement of the card 80 in the Y-direction. This arrangement enables the two regulating portions 32 to directly sandwich the card 80 in the Y-direction. By making the distance D1 in the Y-direction between the two regulating portions 32 almost equal to a distance D4 in the Y-direction between the two regulated surfaces 84, or a size D4 of the card 80 in the Y-direction, the movement of the card 80 in the Y-direction can be reduced even when the cover 50 is irregularly moved relative to the base 20 because of the play provided to the hinge mechanism 60 (see FIG. 1). Thus, the present embodiment provides the connector 10 configured to reduce a shift (movable distance) of the card 80 in the Y-direction.

According to the present embodiment, when the cover 50 is located at the close position, or the position shown in FIG. 9, under the state where the card 80 is held by the card-holding portions 54, the contacts 70 are brought into contact with the electrodes (not shown) of the card 80, respectively, while being resiliently deformed. Meanwhile, a front end of the card 80 is in contact with a rear surface of the front wall 24 of the base 20, so that the card 80 is positioned in the X-direction. In addition, since the movable distance of the card 80 in the Y-direction is reduced, each of the contact portions 78 of the contacts 70 is reliably brought into contact with the corresponding electrode even in a structure in which the contacts 70 are arranged in the Y-direction with narrow intervals. Thus, according to the present embodiment, reliability of electrical connection between the electrodes and the contacts 70 can be improved.

Referring to FIGS. 4 and 5, according to the present embodiment, when the cover 50 is located at the close position, or the position shown in FIGS. 4 and 5, the outside portion 542 of each of the card-holding portions 54 is located between the corresponding regulating portion 32 and the hinge mechanism 60 in the X-direction. In other words, each of the regulating portions 32 is far from the hinge mechanism 60 in the X-direction in comparison with the corresponding outside portion 542. Referring to FIG. 9, according to this arrangement, the movable distance of the card 80 in the Y-direction can be more reliably reduced. However, the present invention is not limited thereto. For example, each of the regulating portions 32 may be near to the hinge mechanism 60 in the X-direction in comparison with the corresponding outside portion 542.

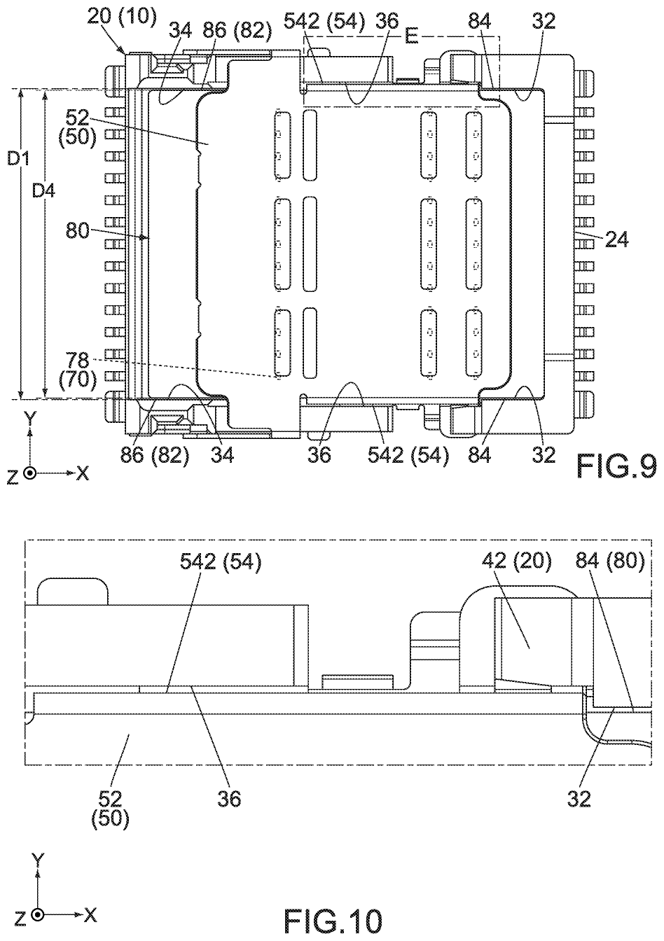

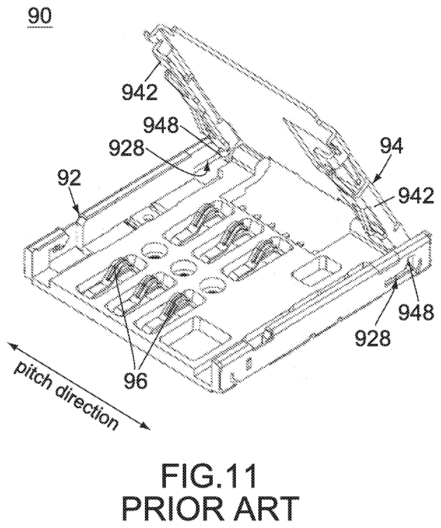

Referring to FIGS. 9 and 10, according to the present embodiment, when the cover 50 is located at the close position, or the position shown in FIGS. 9 and 10, each of the regulated surfaces 84 of the card 80 is located at the front end of the card 80 and faces the regulating portion 32 in the Y-direction with a slight distance from the regulating portion 32. According to this arrangement, the movable distance of the card 80 in the Y-direction can be more reliably reduced. However, the present invention is not limited thereto. For example, when the cover 50 is located at the close position, each of the regulated surfaces 84 of the card 80 may be in contact with the regulating portion 32 in the Y-direction.

Referring to FIGS. 4 and 5, according to the present embodiment, the two regulating portions 32 are located at positions same as each other in the X-direction. However, the present invention is not limited thereto, but the two regulating portions 32 may be located at positions different from each other in the X-direction.

Referring to FIGS. 1 and 2, the base 20 of the present embodiment has two additional regulating portions 34 in addition to the regulating portions 32. The additional regulating portions 34 correspond to the card-holding portions 54 of the cover 50, respectively. Each of the additional regulating portions 34 of the present embodiment is an inner surface of a rear part of the rear portion 226 of the sidewall 22 in the Y-direction and is a plane in parallel to the XZ-plane. However, the present invention is not limited thereto, but the shape of each of the additional regulating portions 34 and the arrangement of the additional regulating portions 34 can be modified variously as necessary. For example, each of the additional regulating portions 34 may be a curved surface.

Referring to FIG. 2, each of the additional regulating portions 34 faces inward in the Y-direction. The two additional regulating portions 34 are apart from each other in the Y-direction. Referring to FIGS. 4 and 5, the two additional regulating portions 34 of the present embodiment are apart from each other by the distance D1 in the Y-direction. As previously described, the distance D1 is shorter than the distance D2 between the outside portions 542 of the two card-holding portions 54 in the Y-direction. Thus, when the cover 50 is located at the close position, or the position shown in FIGS. 4 and 5, each of the additional regulating portions 34 is located inward of the outside portion 542 of the corresponding card-holding portion 54 in the Y-direction. When the cover 50 is located at the close position, each of the additional regulating portions 34 is located at a position different from that of the outside portion 542 of the corresponding card-holding portion 54 in the X-direction.

According to the present embodiment, when the cover 50 is located at the close position, the outside portion 542 of each of the card-holding portions 54 is located between the corresponding regulating portion 32 and the corresponding additional regulating portion 34 in the X-direction. In other words, each of the additional regulating portions 34 is near to the hinge mechanism 60 in the X-direction in comparison with the corresponding outside portion 542. Referring to FIG. 9, according to the present embodiment, when the cover 50 is located at the close position, or the position shown in FIG. 9, each of the additional regulated surfaces 86 of the card 80 is located at a rear end of the card 80 and faces the additional regulating portion 34 in the Y-direction with a slight distance from the additional regulating portion 34 or is in contact with the additional regulating portion 34 in the Y-direction.

Because the present embodiment is provided with the additional regulating portions 34 which are arranged as describe above, the movable distance of the card 80 in the Y-direction can be more reliably reduced. In detail, the additional regulating portions 34, which are arranged as described above, are configured to sandwich the card 80 in the Y-direction similarly to the regulating portions 32. Thus, the regulating portions 32 and the additional regulating portions 34 position the four corners of the card 80 in the XY-plane. However, the present invention is not limited thereto, but the additional regulating portions 34 may be provided as necessary.

Referring to FIGS. 4 and 5, according to the present embodiment, the two additional regulating portions 34 are located at positions same as each other in the X-direction. Each of the additional regulating portions 34 is located at a position same as that of the corresponding regulating portion 32 in the Y-direction. However, the present invention is not limited thereto. For example, the two additional regulating portions 34 may be located at positions different from each other in the X-direction. Each of the additional regulating portions 34 may be located at a position different from that of the corresponding regulating portion 32 in the Y-direction. In other words, the distance between the two additional regulating portions 34 in the Y-direction (see the distance D1 in FIG. 5) may be different from the distance between the two regulating portions 32 in the Y-direction (see the distance D1 in FIG. 5).

Referring to FIGS. 1 and 2, the base 20 of the present embodiment has two cover-regulating portions 36 which correspond to the card-holding portions 54 of the cover 50, respectively. Each of the cover-regulating portions 36 of the present embodiment is an inner surface of a front part of the rear portion 226 of the sidewall 22 in the Y-direction and is a plane in parallel to the XZ-plane. However, the present invention is not limited thereto, but the shape of each of the cover-regulating portions 36 and the arrangement of the cover-regulating portions 36 can be modified variously as necessary. For example, each of the cover-regulating portions 36 may be a curved surface.

Referring to FIG. 2, each of the cover-regulating portions 36 faces inward in the Y-direction. The two cover-regulating portions 36 are apart from each other in the Y-direction. Referring to FIGS. 4 and 5, the two cover-regulating portions 36 correspond to the regulating portions 32, respectively, and correspond to the additional regulating portions 34, respectively. Each of the cover-regulating portions 36 is located between the corresponding regulating portion 32 and the corresponding additional regulating portion 34 in the X-direction. The two cover-regulating portions 36 of the present embodiment are apart from each other by a distance D3 in the Y-direction. The distance D3 is longer than the distance D1 between the two regulating portions 32 and between the two additional regulating portions 34 in the Y-direction. Thus, each of the cover-regulating portions 36 is located outward of the corresponding regulating portion 32 and the corresponding additional regulating portion 34 in the Y-direction.

In the present embodiment, the distance D3 is longer than the distance D2 between the outside portions 542 of the two card-holding portions 54 in the Y-direction. When the cover 50 is located at the close position, or the position shown in FIGS. 4 and 5, each of the cover-regulating portions 36 faces the outside portion 542 of the corresponding card-holding portion 54 in the Y-direction with a slight distance from the outside portion 542.

According to the aforementioned arrangement of the cover-regulating portions 36, when the cover 50 is located at the close position under a state where the card 80 (see FIG. 9) is not held, an irregular movement of the cover 50 can be prevented. However, the present invention is not limited thereto, but the cover-regulating portions 36 may be provided as necessary. Moreover, the arrangement of the cover-regulating portions 36 can be modified variously. For example, when the cover 50 is located at the close position, each of the cover-regulating portions 36 may be in contact with the corresponding card-holding portion 54. Thus, each of the cover-regulating portions 36 may be in contact with or may face the outside portion 542 of the corresponding card-holding portion 54 in the Y-direction.

Referring to FIGS. 4 and 5, the two cover-regulating portions 36 of the present embodiment are located at positions same as each other in the X-direction. However, the present invention is not limited thereto, but the two cover-regulating portions 36 may be located at positions different from each other in the X-direction.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. A connector connectable to a card, wherein:
the connector comprises a base, a plurality of contacts and a cover;
the base holds the contacts;
the contacts are arranged in a pitch direction;
the base is formed with a card-accommodation portion in which the card is accommodatable;
the cover has a cover body portion and two card-holding portions;
each of the card-holding portions is connected to the cover body portion;
the two card-holding portions are apart from each other in the pitch direction and are arranged to sandwich and hold the card therebetween in the pitch direction;
the cover is attached to the base via a hinge mechanism and is movable relative to the base between an open position and a close position;
when the cover is located at the open position, the card-accommodation portion is exposed upward in an upper-lower direction perpendicular to the pitch direction;
when the cover is located at the close position, the cover body portion covers, at least in part, the card-accommodation portion from above, and each of the card-holding portions is located, at least in part, in the card-accommodation portion;
the base has two regulating portions which correspond to the card-holding portions, respectively;
the two regulating portions are apart from each other in the pitch direction;
each of the regulating portions faces inward in the pitch direction;
each of the card-holding portions has an outside portion which faces outward in the pitch direction;
when the cover is located at the close position, each of the regulating portions is located inward of the outside portion of a corresponding one of the card-holding portions in the pitch direction and is located at a position different from that of the outside portion of the corresponding one of the card-holding portions in a front-rear direction perpendicular to both the pitch direction and the upper-lower direction; and
when the cover is located at the close position under a state where the card is held by the card-holding portions, the two regulating portions sandwich the card therebetween in the pitch direction and regulate a movement of the card in the pitch direction.

2. The connector as recited in claim 1, wherein when the cover is located at the close position, the outside portion of each of the card-holding portions is located between a corresponding one of the regulating portions and the hinge mechanism in the front-rear direction.

3. The connector as recited in claim 1, wherein:
the base has two additional regulating portions which correspond to the card-holding portions, respectively;
the two additional regulating portions are apart from each other in the pitch direction;
each of the additional regulating portions faces inward in the pitch direction; and
when the cover is located at the close position, each of the additional regulating portions is located inward of the outside portion of a corresponding one of the card-holding portions in the pitch direction, and the outside portion of each of the card-holding portions is located between a corresponding one of the regulating portions and a corresponding one of the additional regulating portions in the front-rear direction.

4. The connector as recited in claim 1, wherein:
the base has two cover-regulating portions which correspond to the card-holding portions, respectively;
the two cover-regulating portions are apart from each other in the pitch direction;
each of the cover-regulating portions faces inward in the pitch direction and is located outward of a corresponding one of the regulating portions in the pitch direction; and
when the cover is located at the close position, each of the cover-regulating portions is in contact with or faces the outside portion of a corresponding one of the card-holding portions in the pitch direction.

5. The connector as recited in claim 1, wherein:
the cover has two locked portions which correspond to the card-holding portions, respectively;
each of the locked portions extends outward from a corresponding one of the card-holding portions in the pitch direction;
the base has two receiving portions which correspond to the card-holding portions, respectively, and has two lock portions which correspond to the receiving portions, respectively;
each of the lock portions is located outward of a corresponding one of the receiving portions in the pitch direction; and
when the cover is located at the close position, each of the receiving portions partially receives a corresponding one of the card-holding portions, and each of the lock portions locks a corresponding one of the locked portions.
